(19) United States
(12) Patent Application Publication
(10) Pub. No.: US 2016/0215386 A1
(43) Pub. Date: Jul. 28, 2016

(54) MODULATION OF REVERSE VOLTAGE LIMITED WAVEFORMS IN SPUTTERING DEPOSITION CHAMBERS

(71) Applicant: ITN ENERGY SYSTEMS, INC., Littleton, CO (US)

(72) Inventor: Michael Wayne Stowell, Loveland, CO (US)

(21) Appl. No.: 14/917,511

(22) PCT Filed: Sep. 9, 2014
(86) PCT No.: PCT/US2014/054747

§ 371 Date: Mar. 8, 2016

Related U.S. Application Data
(60) Provisional application No. 61/875,570, filed on Sep. 9, 2013.

(51) Int. Cl. C23C 14/54; H01J 37/34; C23C 14/34

(52) U.S. Cl. CPC C23C 14/542; C23C 14/3485; H01J 37/3467; H01J 37/3476; H01J 37/3444

(57) ABSTRACT

Modulation of a waveform applied to a cathode of a sputtering deposition chamber regulates the sputtering rate and density and kinetic energy of ions in a sputtering deposition chamber. A waveform may include a pulsed DC waveform with a modulated AC signal superimposed on the pulsed DC waveform. The DC waveform may have a reverse voltage period. A reverse voltage limiting circuit is provided so as to limit the reverse voltage spike to a selected reverse voltage threshold. One may modulate various properties of the waveform to increase or decrease sputtering rates and thin-film quality.

### INTRODUCTION

This application is being filed on 9 Sep. 2014, as a PCT International patent application, and claims priority to U.S. Provisional Patent Application No. 61/875,570, filed Sep. 9, 2013, the disclosure of which is hereby incorporated by reference herein in its entirety.

Thin film devices, including electrochromic devices and batteries, have a variety of applications. Flat panel displays, semiconductors, flexible displays, electrochromic windows, and touch screen displays may all incorporate thin film devices.

One technique to create thin film devices is sputtering deposition. In sputtering, charged particles (ions) are used to both atomize material from a sputtering target and to impact the quality of the resulting thin films. As such, controlling the energy and density of ions may be desirous.

For example, material striking a substrate with too much energy can destroy the structure of material previously deposited onto the substrate. Material having too low energy can fail to form proper lattice structures. Indeed, atoms that absorb with too low surface energy that they fail to overcome the Schwoebel-Ehrlich barrier can result in a substrate with a surface microstructure having interstitial voids. This will affect the properties of the deposited layer and ultimately the device itself.

One major drawback of the high energy ion production and substrate bombardment is that the ion energies can be too high and degrade the films properties through many factors such as, re-nucleation, depending upon the material and layers grown as well as the source and configuration. Therefore the need has arisen to control the ion energy level to better optimize the films growth and films properties.

It is with respect to these and other considerations that embodiments have been made. Also, although relatively specific problems have been discussed, it should be understood that the embodiments should not be limited to solving the specific problems identified herein.

Modulation of a waveform applied to a cathode of a sputtering deposition chamber regulates the sputtering rate and density and kinetic energy of ions in a sputtering deposition chamber. A waveform may include a pulsed DC waveform with a modulated AC signal superimposed on the pulsed DC waveform. The DC waveform may have a reverse voltage period. A reverse voltage limiting circuit is provided so as to limit the reverse voltage spike to a selected reverse voltage threshold. One may modulate various properties of the waveform to increase or decrease sputtering rates and thin-film quality.

The technology disclosed includes a method of controlling ions in a sputtering system. The sputtering system includes at least one cathode. The method includes generating a modulated power signal. The modulated power signal includes a reverse voltage portion. The reverse voltage portion is limited by a reverse voltage limit. The method further includes providing the modulated power signal to the cathode.

Additionally, the technology includes a method for controlling ion density in a sputtering system. The method includes providing a power signal to the sputtering system. The method further includes varying at least one characteristic of the power signal to control ion density. The characteristic includes at least one of one AC waveform frequency, AC waveform amplitude, pulsed-DC steady state duration, pulsed-DC steady state voltage, reverse voltage portion voltage, reverse voltage portion duration, reverse voltage limit, and pause period, and power signal application period. The power signal includes by a reverse voltage limit.

Additionally, the technology discloses a system for controlling the power applied to cathode of a sputtering deposition chamber. The system includes a pulsed-DC power supply, an AC power supply, and a control circuit. The system is configured to perform the method of generating a modulated power signal. The modulated power signal includes a reverse voltage portion, the reverse voltage portion limited by a reverse voltage limit. The modulated power signal is provided to the cathode.

### BRIEF DESCRIPTION OF THE DRAWINGS

FIG. 1 illustrates the prior art of a planar sputtering cathode system.

FIG. 2 illustrates a thin film with interstitial voids.

FIG. 3 illustrates the prior art of an RF waveform super positioned on a pulsed DC waveform.

FIG. 4 illustrates a waveform that combines an RF waveform super positioned on pulsed-DC with a reverse voltage limiting threshold.

FIG. 5 illustrates the expected resistivity properties of thin films when a waveform 300 is applied to a cathode.

FIG. 6 illustrates the expected resistivity properties of thin films when a composite waveform 400 is applied to a cathode.

FIG. 7 illustrates a method of applying an RF waveform super positioned on a pulsed DC waveform combined with reverse voltage threshold to a cathode of a sputtering deposition process.

FIG. 7A illustrates the apply a pulsed DC waveform to a cathode operation.

FIG. 7B illustrates an apply an RF waveform operation.

FIG. 8 illustrates a system to apply an RF and pulsed DC waveform combined with reverse voltage threshold to a cathode of a sputtering deposition process.

FIG. 9 illustrates an embodiment of a waveform with modulated waveform sequences.

### DETAILED DESCRIPTION

The systems and methods described herein are directed at modifying waveform sequences when applying waveform energy to a cathode in a sputtering deposition chamber for thin film creation. The waveform of the applied energy may be such that ion generation rates, ion energy distributions, and sputtering rates are controlled. Moreover, these and other parameters may be controlled to vary over time to create thin-films with certain properties. Various sputtering systems include rotatable cathode and planar magnetron sputtering systems.

The embodiments described herein are described with respect to planar sputtering cathode systems. However, it will be recognized that the technology described herein may be adapted to other sputtering techniques and configurations where ion interaction with deposited materials is desired.

The use of Pulsed DC and AC power supplies in sputtering has benefited many film deposition processes and film properties by better controlling the sputtering energies. This control is achieved due to the fact that these power supplies inherently extinguish and re-ignite the plasma at user defined frequencies and intensities. At the beginning and end of each power pulse or plasma ignition/extinguish from either of these systems, there is a broader distribution of electron energies producing ions and greater percentage of the sputtered species generated. In DC and Composite DC processes, because there is only an initial plasma ignition, the distribution stabilizes out to a lower average value of electron energy.

With this in mind it can be said that for AC and pulsed power there are many beginnings and endings to increase the average electron/ion energy and densities to a much higher value thus giving this benefit to the process. By controlling the pulse duration and duty cycle one can control the electron/ion energies and the relative number of generated specific sputtered species and Ions. Using pulsed power can give the operator effective control over more of the sputtered thin film properties.

Through the use of a modulation signal the user can control the frequency, duty cycle, etc. rapidly thereby changing the source from a sputtered species generating device to an ion source generating device. For instance, at one frequency, the sputtering system may have a low ion density and sputtering rate high. At another frequency, the sputtering system may have a high ion density and low sputtering rate. By modulating the waveform, the sputtering system can then effectively alternate between these regimes to optimize growth rate and film properties.

For example, the power supplies reverse their polarity during a portion of the cycle (whether it being AC or Pulsed DC) and combine with the plasma potentials. This drives the sputtering cathode much more positive during the reversal than the power supply actually delivers, thus producing higher voltages and therefore higher energy ions during this portion of the cycle. During this polarity reversal the high energy (mostly positive) ions are driven away from the cathode toward the substrate due to the cathodes positive potential. These ions strike the growing film benefiting its growth, especially in kinetically limited growth, through collisional cascading as well as increased Adatom surface mobility.

At present, the pulse frequency and reversal time of the power supplies can be increased to increase the density of high energy ions (due to more cycles of cathode high reversal voltage), or decreased to decrease the ion density ions (due to less cycles of cathode high reversal voltage). However, the energy of the ions changes with the cathode reverse voltage unpredictably with increasing or decreasing frequency and reverse time. Reversal voltages of 300 volts or higher, regardless of the frequency and reverse time, are typical depending upon the capacitance and inductance in the cathode's circuit.

The present invention employs a reverse voltage limiting circuit that allows the user to independently control the ion energies generated during this reversal period. Also a benefit of this limiting of the ion energies allows the user to vary the ion density/flux independently of the ion energy, by varying the frequency and reverse times. The combination of reverse voltage limiting (active or passive) and modulation of sputtering cathode potentials to control ion/electron energy and densities simultaneously to affect new plasma and film properties.

The embodiment includes a configuration where components and controls are integrated into the power supply, a separate unit, matching network and or filter or at the connection to the cathode itself.

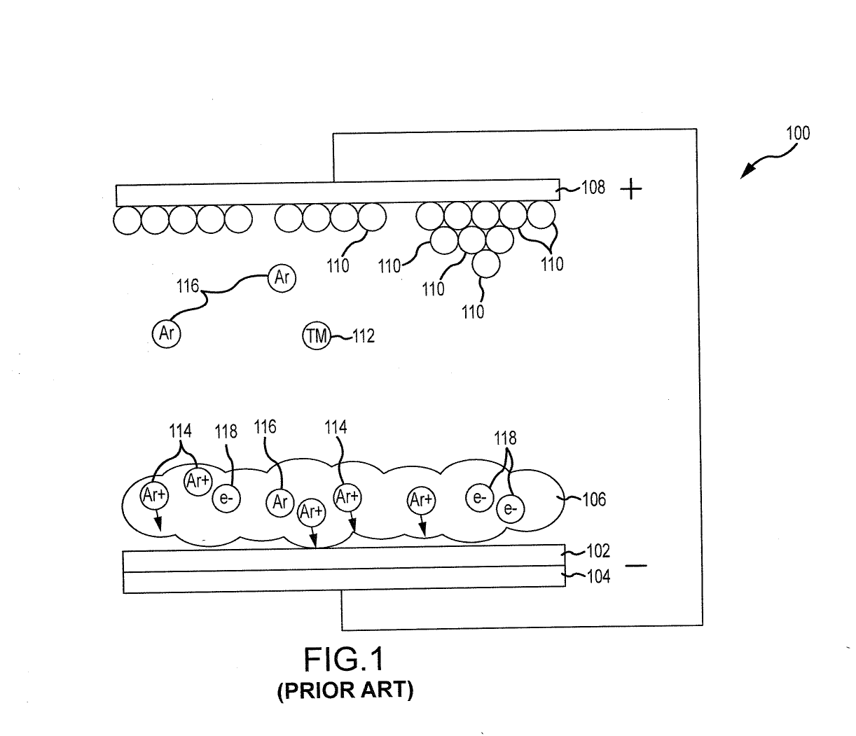

FIG. 1 represents prior art of a planar sputtering cathode system 100. Planar sputtering cathode system 100 includes a target 102, a cathode 104, a plasma sheath 106, a substrate 108, deposited material 110, a sputtered species 112, ions 114, and process gas particles 116.

In a planar sputtering cathode system 100, a target 102 may have a magnetic field applied to it. This magnetic field helps contain a plasma sheath 106 to the surface of a target 102 or near the surface of target 102. The magnetic field may confine electrons and secondary electrons to on and/or near the surface of a target. In an embodiment, the characteristics of the magnetic field affect the path of the electrons that travel around the surface of a target 102. The target 102 may be any material suitable for sputtering.

A cathode 104 has a voltage applied to it. In embodiments, a DC current is applied to a cathode 104. This DC current, which may create a 300V energy potential between the cathode 104 and the substrate 108, may be applied in order to ignite the plasma and generate ions 114. Some electrons 118 produced within the plasma sheath 106 have sufficient energy to meet the first ionization potential of the process gas particle 116. Consequently, some process gas particles 116 become positive ions 114.

Ions 114 produced in the plasma sheath 106 have an energy distribution. The energy distribution of the produced ions 114 is dependent on, inter alia, the current applied to the cathode 104, the waveform of that current, and the process gas used in the system.

Positive ions 114 accelerate toward a negatively charged cathode 104. The positive ions may collide with a target 102 and cause a sputtered species 112 to be ejected. Some of the sputtered species 112 will then be deposited onto a substrate 108. As such, sputtered species 112 may be the same material as both the target 102 and the deposited material 110. In other embodiments, the target material reacts with one or more process gases and the resulting compound deposits onto the substrate 108. This reaction may occur at the surface of the target 102, during the travel of sputtered species 112, and/or after material has been deposited on the substrate to form deposited material 110.

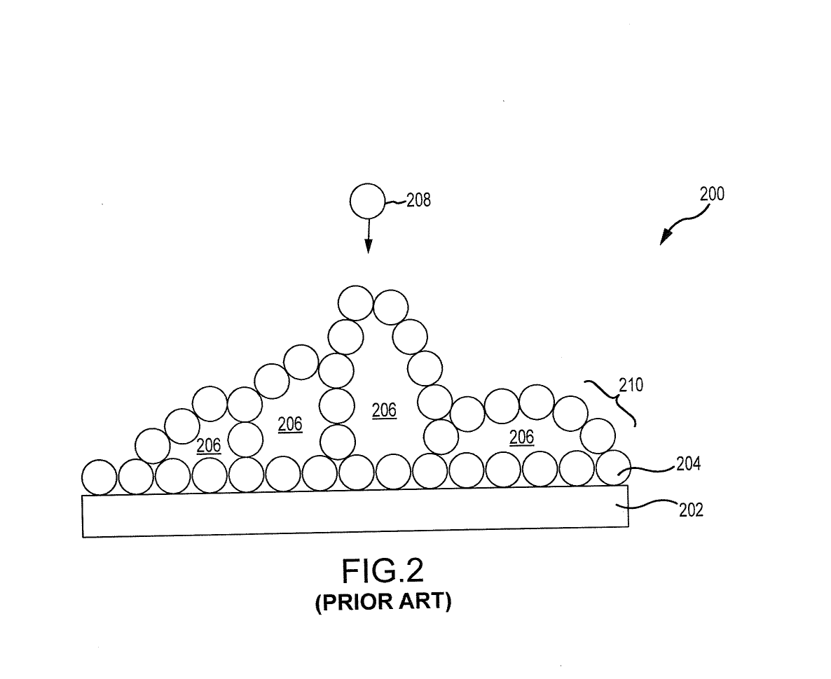

Deposited material 110 will form structures, and those structures depend on the kinetic energy of incoming sputtered species 112. For example, a layer of deposited material 110 may be present on the substrate 108. The deposited material 110, given certain process conditions, will form a lattice or crystal structure. A lattice structure occurs when the deposited material 110 is arranged in a substantially ordered manner. In other process conditions, however, a lattice structure will fail to form. Process conditions include the presences of impurities, the kinetic energy of the sputtered species 112 at the time of colliding with deposited material 110, and any other mechanisms that may control the transfer of kinetic energy to the deposited material 110. In embodiments, one such mechanism is to control the energy of ions 114. The relationship between kinetic energy and lattice structure is described more fully with reference to FIG. 2.

In general, the energy of sputtered species 112 is directly proportional to the kinetic energy of the ions 114. For example, some ions 114 collide with the target 102 and transfer energy to the target 102. As a result of this collision, some material of the target 102 is ejected and becomes a sputtered species 112. Thus, high-energy ions 114 striking a target 102 will cause sputtered species 112 to have a greater kinetic than low-energy ions 114. Additionally, upon striking the substrate 108, the sputtered species 112 transfers kinetic energy to the previously deposited material 110.

Another way ions 114 may affect the kinetic energy transferred to deposited material 110 is through ion 114 bombardment of the deposited material 110. For example, in instances where the polarity of the cathode is reversed, the positive ions 114 may accelerate toward a negatively charged substrate 108. In another embodiment, the substrate 108 does not hold a charge and the positive ions 114 accelerate toward a negatively charged area near a substrate 108. Ions 114 with a high kinetic energy that collide with deposited material 110 will transfer more kinetic energy than ions 114 with a lower kinetic energy. Furthermore, the more ions 114 that bombard deposited material 110, the more kinetic energy will transfer to the deposited material 110. Thus, the rate of ion 114 bombardment affects the kinetic energy transferred to deposited material 110.

With respect to FIG. 2, FIG. 2 illustrates a thin film 200. In the embodiment shown, a substrate 202 is illustrated with a thin film of deposited material 204. Thin films with interstitial voids are known in the art. The deposited thin film 200 is illustrated as having a substrate 202, a deposited material 204, interstitial voids 206, and a sputtered species 208.

For certain thin films, it may be desirous to remove or limit the number of interstitial voids 206 that may form during deposition. For example, interstitial voids increase the electrical resistivity of thin films for certain materials. Controlling the transfer of kinetic energy to deposited material 204 may limit the number of interstitial voids 206 that form during deposition, and thus reduce the electrical resistivity of the thin film.

For certain deposited materials 204, interstitial voids 206 occur when a target material fails to have sufficient kinetic energy to meet or overcome the Schwoebel-Ehrlich barrier. Failure to meet the Schwoebel-Ehrlich barrier causes deposited material 204 to form sloping regions 210. Sloping regions 210 tend to cause interstitial voids 206. On the other hand, deposited material 204 that has sufficient energy to overcome the Schwoebel-Ehrlich barrier may form a surface with a high surface symmetry. That is, the deposited material 204 will form less sloping regions and arrange more evenly across the surface of the substrate 202. As such, transfer of kinetic energy to a deposited material 204 may allow the deposited material 204 to have a sufficient energy to overcome the Schwoebel-Ehrlich barrier.

Additionally, it may also be desirous to limit the amount of kinetic energy transferred because too much kinetic energy transfer may damage the fidelity of the deposited material's 204 lattice structure. Damaging the lattice structure may also increase the electrical resistivity of a thin film.

Controlling the transfer of kinetic energy may occur by controlling the kinetic energy of incoming sputtered species 208. Controlling the transfer of energy may also occur through controlling ion kinetic energy and the rate of ion bombardment. Energy transfer to a deposited material is discussed further with reference to FIG. 1.

As such, it may be desirable to have an energy waveform applied to a cathode that can create ions at an appropriate rate and an appropriate energy for generating thin films with a targeted electrical resistance. This waveform will be referred to as a finely tuned waveform.

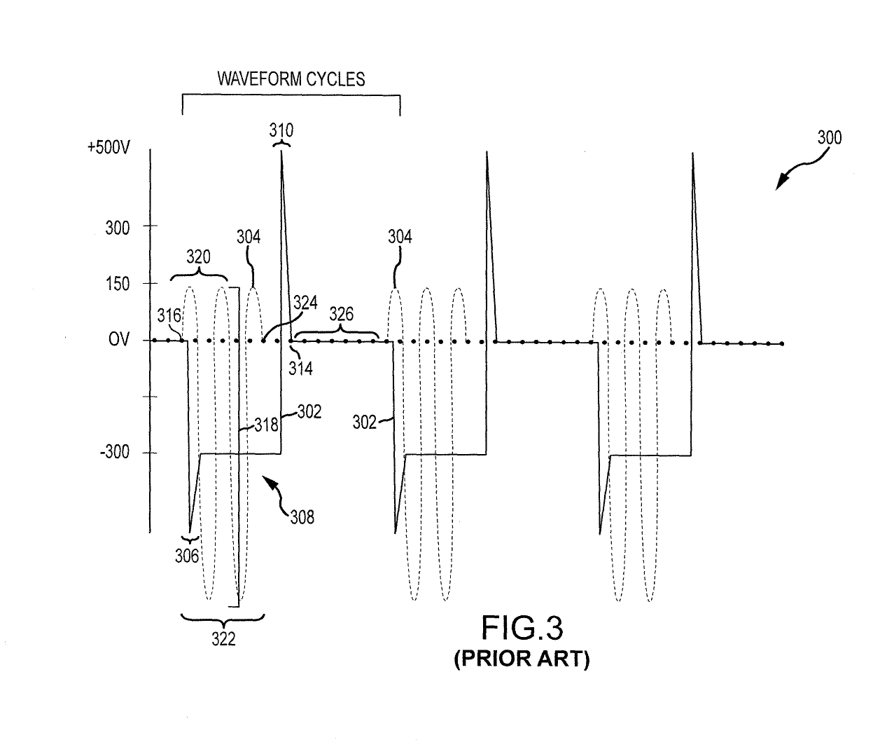

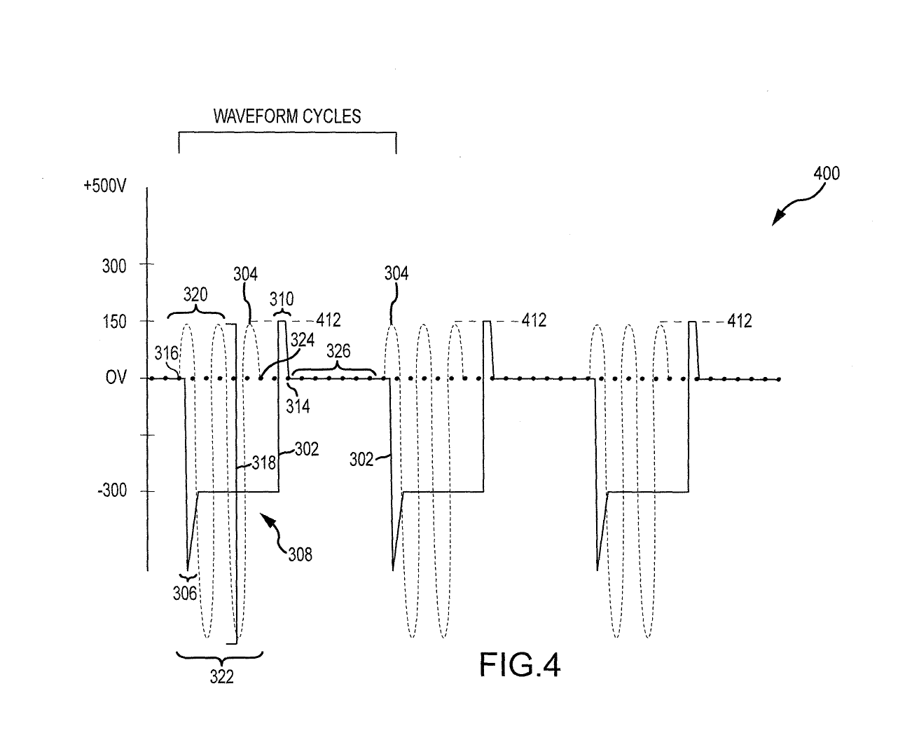

With reference to FIGS. 3 and 4, FIG. 3 illustrates the prior art of an RF waveform super positioned on a pulsed DC waveform 300. Though FIG. 3 and FIG. 4 illustrate an RF waveform, it will be appreciated that the technology disclosed with reference to FIG. 4 contemplates using other forms of power besides RF to generate a high frequency waveform (such as an alternating current). FIG. 4, which is not prior art, illustrates a composite waveform 400 that combines an RF waveform super positioned on pulsed-DC waveform with a reverse voltage limiting threshold. Waveform 300 and composite waveform 400 have a pulsed-DC waveform 302 and an RF waveform 304. Composite waveform 400 may be applied to a cathode of a sputtering deposition process in order to adjust the energy of the plasma.

Additionally the pulsed-DC waveform 302 includes a plasma ignition portion 306, a steady-state portion 308, a reverse DC voltage portion 310, and a pulsed-DC termination point 314.

In an embodiment, the application of waveform 300 or composite waveform 400 to a cathode ignites a plasma in a sputtering deposition chamber. The plasma ignition occurs contemporaneous with a plasma ignition portion 306. In another embodiment, the application of an RF waveform 304 causes a plasma to ignite.

During plasma ignition, ions are generated. When a waveform 300 or a composite waveform 400 is applied to a cathode of a sputtering deposition chamber, generation of positive ions continues through the duration of a steady-state portion 308. The positive charge of these ions causes the ions to propel toward a negatively charged cathode. The resulting collision with the target propels target material toward a substrate for deposition. The steady-state portion 308 may have a voltage that is set at −50V, −60V, −70V, −80V, −90V, −100V, −110V, −120V, −130V, −140V, −150V, −160V, −170V, −180V, −190V, −200V, −210V, −220V, −230V, −240V, −250V, −260V, −270V, −280V, −290V, −300V, −310V, −320V, −330V, −340V, −350V, −360V, −370V, −380V, −390V, −400V, −410V, −420V, −430V, −440V, −450V, −460V, −470V, −480V, −490V, and −500V.

In the waveform 300 and composite waveform 400 shown, a reverse DC voltage portion 310 occurs after steady-state portion 308. When applied to a cathode, the reverse DC voltage portion 310 changes the polarity of the cathode from negative to positive.

As shown, waveform 300 and composite waveform 400 have an RF waveform 304 superimposed on the pulsed-DC waveform 302. An RF waveform has an RF initiation point 316, an amplitude 318, a frequency 320, and an RF application duration 322. As illustrated, the waveforms 300 and 400 have an RF power termination point 324.

In embodiments, an RF initiation point 316 may occur at or near the same time as the plasma ignition portion 306. When the waveform 300 or waveform 400 is applied to a cathode, RF initiation point 316 marks the initiation of the application of the RF waveform 304 to a cathode of a sputtering deposition chamber. When applying RF waveform 304 to a cathode, varying the frequency 320 and the amplitude 318 of the RF waveform 304 will generate ions with certain energy distributions. Furthermore, the density of ions created in a plasma sheath is directly proportional to the frequency 320. For example, at 13.56 mhz an RF waveform 304 may create ions at a faster rate than a lower frequency. Ion generation occurs during RF application duration 322 until an RF power termination point 324. RF power termination point 324 may occur sometime before a reverse DC voltage portion 310. Ensuring that the RF power termination point 324 occurs before a reverse DC voltage portion 310 may be accomplished by various analog and digital control techniques, or some combination of the two techniques.

Alternatively, RF is applied continuously until the final waveform cycle. In this embodiment, the RF is applied continuously through all stages of the pulsed-DC waveform 302.

A reverse DC voltage portion 310 may occur by design or may be caused intrinsically by shutting off a DC power supply. When applied to a cathode, the reverse DC voltage portion 310 reverses the polarity of the cathode from negative to positive. When this reversal occurs in a sputtering deposition chamber, the positive ions will accelerate toward the now negatively charged substrate (or a negatively charged area near the substrate). This depletes the ion density of the plasma sheath and substantially halts the deposition of sputtered species. In the prior art waveform 300, the kinetic energy of the ions striking the substrate is directly proportional to the magnitude of the reverse DC voltage portion 310.

In embodiments, it may be desirous to limit the magnitude of the reverse voltage. Composite waveform 400 includes a reverse voltage threshold 412. This limits the magnitude of the reverse voltage limiting portion. Limiting the magnitude of the reverse voltage limits the kinetic energy of the ions accelerating toward the substrate during a reverse DC voltage portion 310.

Limiting the reverse voltage may be accomplished through electronic devices along with analog and digital controllers. In some embodiments where the target is non-metallic, a reverse voltage limiting may interfere with the RF waveform. As described in greater detail below, the systems and methods disclosed herein account for this and prevent interference with the RF waveform while still allowing the reverse DC voltage to be limited.

Application of the reverse voltage threshold 412 may be depend on the specific sputtering environment. For example, in an embodiment where the process gas is Ar, and the deposition material is transparent conductive oxide (“TCO”), a reverse DC voltage portion 310 may last for between 0.5 and 10 mircoseconds. In embodiments, the reverse DC voltage portion lasts for a microsecond. Additionally, a reverse voltage threshold 312 may be set between 100 and 300 volts.

Furthermore, the composite waveform 400 may be applied at a 10 kHz, 20 kHz, 30 kHz, 40 kHz, 50 kHz, 60 kHz, 70 kHz, 80 kHz, 90 kHz, 100 kHz, 110 kHz, 120 kHz, 130 kHz, 140 kHz, 150 kHz, 160 kHz, 170 kHz, 180 kHz, 190 kHz, 200 kHz, 210 kHz, 220 kHz, 230 kHz, 240 kHz, 250 kHz, 260 kHz, 270 kHz, 280 kHz, 290 kHz, 300 kHz, 310 kHz, 320 kHz, 330 kHz, 340 kHz, 350 kHz, 360 kHz, 370 kHz, 380 kHz, 390 kHz, 400 kHz, 410 kHz, 420 kHz, 430 kHz, 440 kHz, 450 kHz, 460 kHz, 470 kHz, 480 kHz, 490 kHz, or 500 kHz.

As shown, full rest period 326 is present in waveform 300 and composite waveform 400. If applied to a cathode, rest period 326 represents the time in which no pulsed-DC power or

RF power is supplied to the cathode. The full rest period 326 is defined as the time between the termination of the application of a power and the next application of a power. A rest period may not be present or may be of a short or long duration relative to the DC pulse duration.

A cycle of a waveform 300 or waveform 400 is calculated by summing the time from the first application of power to the cathode until the end of a rest period 326.

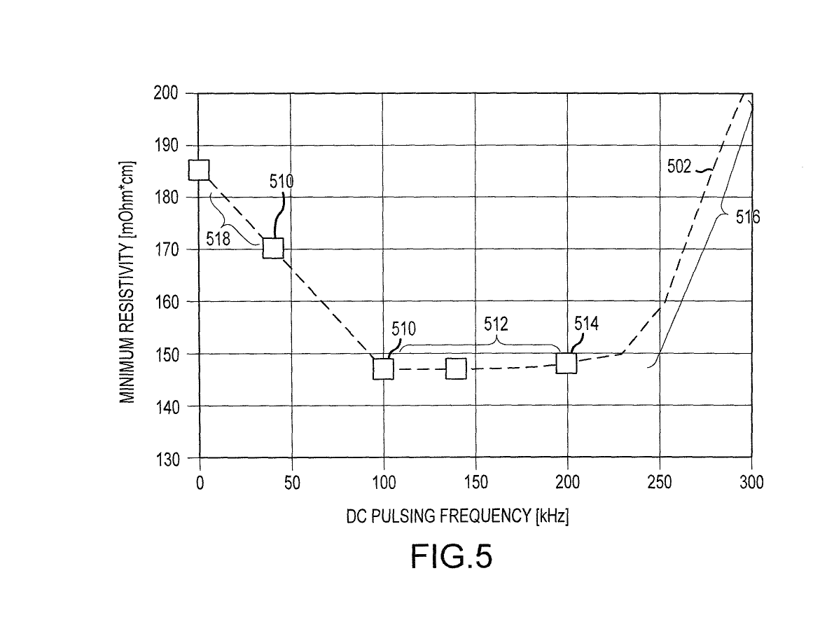

FIG. 5 illustrates the expected resistivity properties of thin films created when a waveform 300 is applied to a cathode. The y-axis of the graph illustrates the minimum resistivity in μOhm*cm. The x-axis represents the frequency at which the DC pulse would be applied to a cathode of a sputtering deposition chamber. Line 502 illustrates the resistivity of a thin-film that may be produced by applying an embodiment waveform 300, i.e., an RF waveform superimposed on pulsed-DC waveform to a cathode of a sputtering deposition chamber.

Line 502 may be understood as having three frequency ranges. In the first range, the minimum resistivity of the thin film decreases in a decreasing resistivity range 508. As illustrated, line 502 illustrates the resistivity decreasing from ˜185 to ˜148 μOhm*cm over the decreasing resistivity range 508. This corresponds to a frequency of 0 to ˜100 kHz DC-pulsed. At a steady-state point 510 the resistivity of the thin film no longer decreases. As illustrated, the steady-state point is ˜100 kHz. The steady-state point 510 marks the start of a steady-state range 512. In a steady-state range 512, the resistivity of the produced thin-film does not vary substantially with varying pulsed-DC frequencies. As illustrated, line 502 has a steady-state 512 that corresponds to a frequency range from 100 kHz to ˜200 kHz. In some embodiments, at an inflection point 514 the resistivity of the thin film begins to increase. As illustrated, the inflection point 514 for line 502 corresponds to a frequency of ˜200 kHz. After the inflection point 514, an increasing resistivity range 516 may be present. In increasing resistivity range 516, the resistivity of the produced thin film increases as frequency of the pulsed-DC increases. As illustrated, line 502 has an increasing resistivity range 516 that corresponds to a frequency of ˜200 kHz to at least 300 kHz.

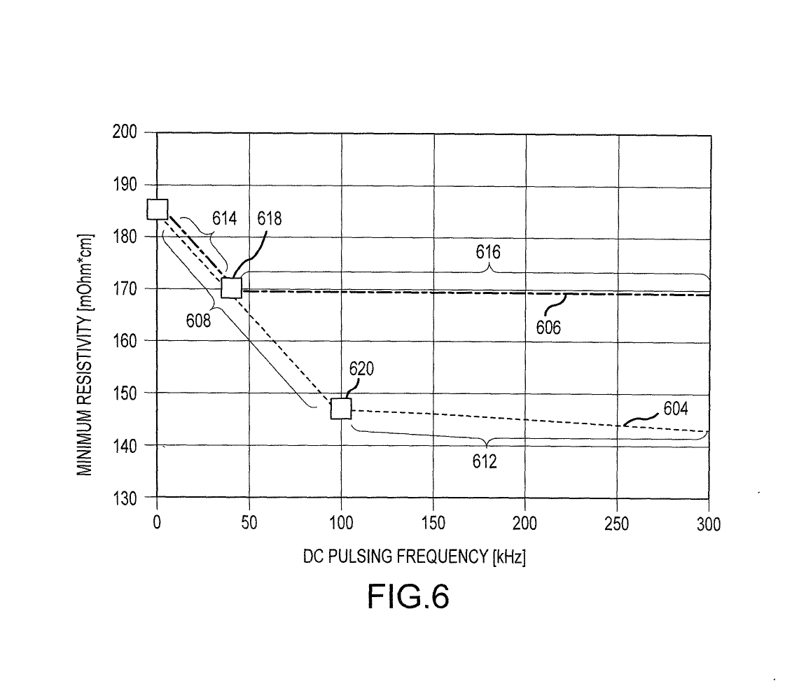

FIG. 6 illustrates the expected resistivity properties of thin films created when a composite waveform 400 is applied to a cathode. The y-axis of the graph illustrates the minimum resistivity in μOhm*cm. The x-axis represents the frequency at which the DC pulse would be applied to a cathode of a sputtering deposition chamber. Line 604 illustrates the resistivity of a thin-film that may be produced by applying an embodiment of a composite waveform 400, i.e., an RF waveform superimposed on pulsed-DC waveform combined with reverse voltage limiting. Additionally, line 606 illustrates the resistivity of a thin-film produced that may be produced by applying an alternative embodiment of a composite waveform 400.

Line 604 may be understood as having two areas, a decreasing resistivity range 608 and steady-state range 612. Additionally, line 606 may be understood as having two areas, a decreasing resistivity range 614 and a steady-state range 616. As illustrated, line 604 has a decreasing resistivity range 612 that is greater than the decreasing resistivity range 614 of line 606. In embodiments, this may be because the composite waveform 400 that produced the results illustrated by line 606 has a lower reverse voltage threshold than the composite waveform 400 that produced the results illustrated by line 604.

As illustrated, lines 604 and lines 606 have no increasing resistivity range. This may occur because the composite waveforms 400 used to produce lines 604 and 608 have a reverse limiting voltage threshold. This reverse threshold may ensure that ions that strike the previously deposited material have a sufficiently low kinetic energy.

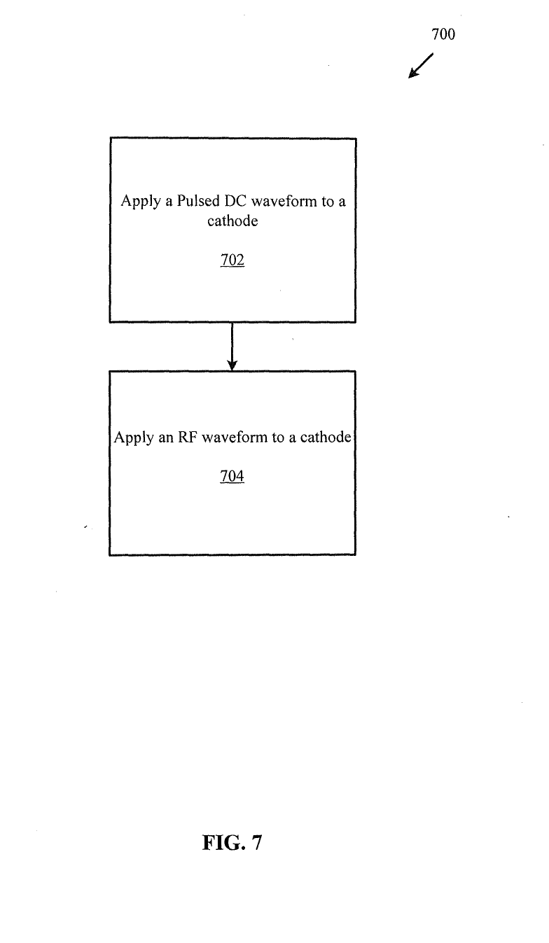

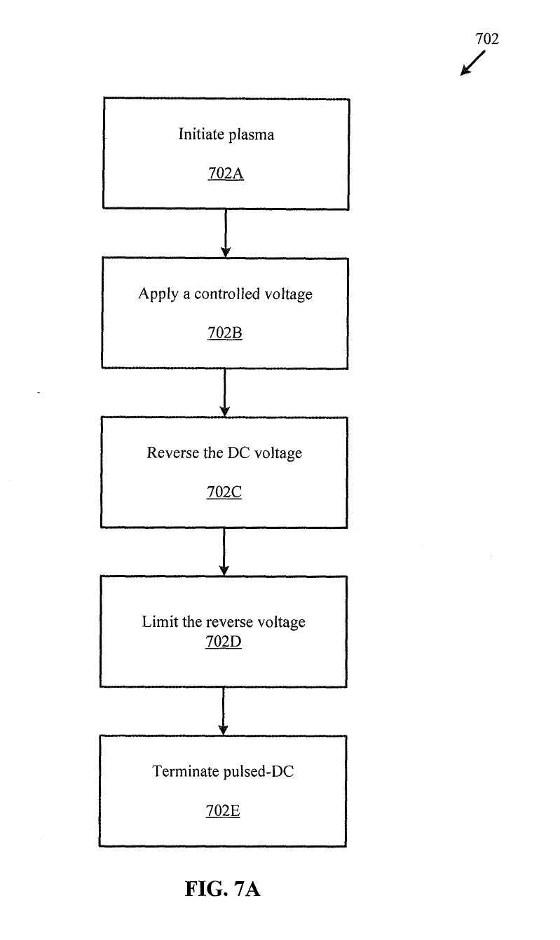

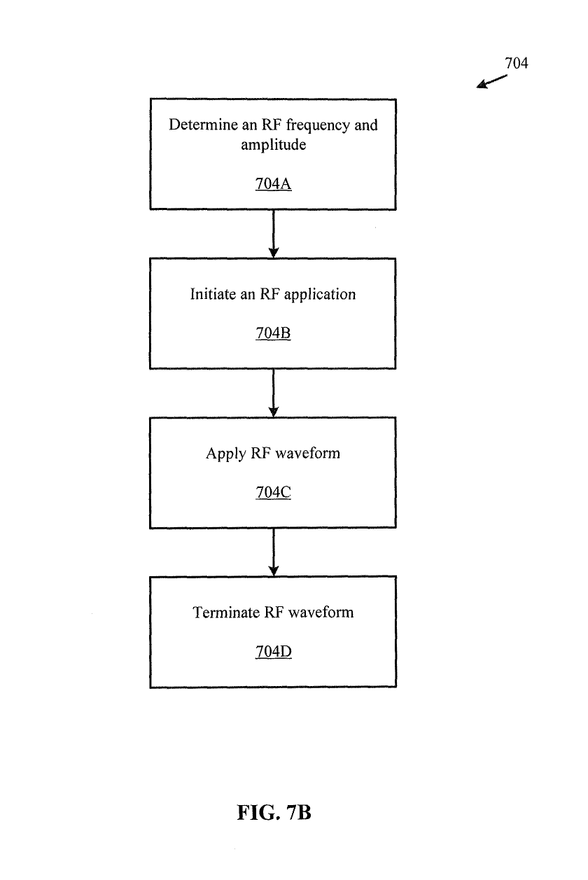

FIG. 7 illustrates a method 700 of applying an RF waveform super positioned on a pulsed DC waveform combined with reverse voltage threshold to a cathode of a sputtering deposition process. The method 700 includes an apply a pulsed DC waveform to a cathode operation 702. The method 700 also includes an apply an RF waveform to a cathode operation 704.

As illustrated, method 700 begins with apply a pulsed DC waveform to a cathode operation 702. In other embodiments, the method 700 begins with an apply an RF waveform to a cathode operation 704. Still in other embodiments, the operations 702 and 704 may occur at the same time.

FIG. 7A illustrates the apply a pulsed DC waveform to a cathode operation 702. The applying a pulsed DC waveform operation 702 includes an initiate plasma operation 702A, apply a controlled voltage operation 702B, a reverse the DC voltage operation 702C, a limit the reverse voltage operation 702D, and a terminate pulsed-DC operation 702E.

The apply a DC waveform to a cathode operation 702 begins with an initiate plasma operation 702A. Initiate plasma operation 702A may result in a negative voltage spike for some period of time. For example, the spike lasts for between 0.5 to 10 microseconds in embodiments. In other embodiments, there is no spike, and an initiate plasma operation 702A merely marks the point at which a pulse DC waveform is first applied to a cathode.

The apply a DC waveform to a cathode operation next proceeds to an apply a controlled voltage operation 702B to a cathode operation. This operation results in a DC being applied for some time period at a substantially fixed voltage. For example, a DC waveform may have a controlled voltage operation 702B between −100V and −300V.

Next, operation 702 proceeds to a reverse the DC voltage operation 702C. In an embodiment, reverse the DC voltage operation 702C causes the voltage to be reversed from negative to positive. As mentioned above, the reverse the DC voltage operation 702C may be an active operation as shown or may be a natural result of the termination of the operation 702B. In an embodiment where the original voltage was positive, the reverse the DC voltage operation 702C causes the voltage to be reversed from positive to negative. In an embodiment, the reverse DC voltage operation 702C causes the DC voltage to go to between +50 and +400V absent a limit the reverse voltage operation 702D described below.

A limit the reverse voltage operation 702D limits the degree to which the reverse the DC voltage operation 702C can reverse the voltage applied to the cathode. In embodiments, the limit the reverse voltage operation 702D causes the reverse voltage to be limited to one of the following voltages +50V, +60V, +70V, +80V, +90V, +100V, +110V, +120V, +130V, +140V, +150V, +160V, +170V, +180V, +190V, +200V, +210V, +220V, +230V, +240V, +250V, +260V, +270V, +280V, +290V, +300V, +310V, +320V, +330V, +340V, +350V, +360V, +370V, +380V, +390V, and +400V. A terminate pulsed-DC operation 702E ends the application of the reverse voltage to a cathode. This may occur naturally as a final result of terminating operation 702B.

The reverse voltage limiting operation 702D is presented here as a separate step, although the reader will recognize that the reverse voltage operation 702C, the limiting operation 702D and the DC pulse termination operation 702E may all occur at the same or substantially the same time and may be, in effect, a single operation. In an embodiment in which the reverse voltage is a transient effect caused by the termination of the DC pulse, the limiting operation 702D is achieved by the simultaneous activation of reverse voltage limiting electronics that prevent the reverse voltage from exceeding the set threshold.

In embodiments where the target is non-metallic, the timed activation of the electronics prevents interference with the applied RF waveform or other desired transient elements of the waveform, which would be detrimentally affected if the limiting electronics were active at all times. In an alternative embodiment, although difficult in practice using currently available technology, the entire waveform may be controlled by software so that the exact desired waveform is delivered at the chamber without the need to rely on inherent properties of the hardware to intrinsically create some or all of the waveform (e.g., the reverse voltage).

FIG. 7B illustrates an apply an RF waveform operation 704. In an embodiment, the apply an RF waveform operation 704 includes a determine an RF frequency and amplitude operation 704A, an initiate an RF application 704B, an apply an RF operation 704C, and a terminate an RF application 704D.

Apply an RF waveform operation 704 begins with a determine an RF frequency and amplitude operation 704A.

Next an initiate an RF application operation 704B initiates the application of an RF waveform to a cathode. The application of the RF waveform to a cathode continues through apply an RF waveform operation 704C. Apply an RF waveform operation 704C may last for a duration of the apply a controlled voltage operation 702B. Alternatively the apply the RF waveform operation 704C may last for the entire duration of all cycles of pulsed-DC waveform.

A terminate an RF application operation 704D stops the application of an RF waveform to a cathode. In embodiments, the terminate an RF application operation occurs before the limit the reverse voltage operation 702D.

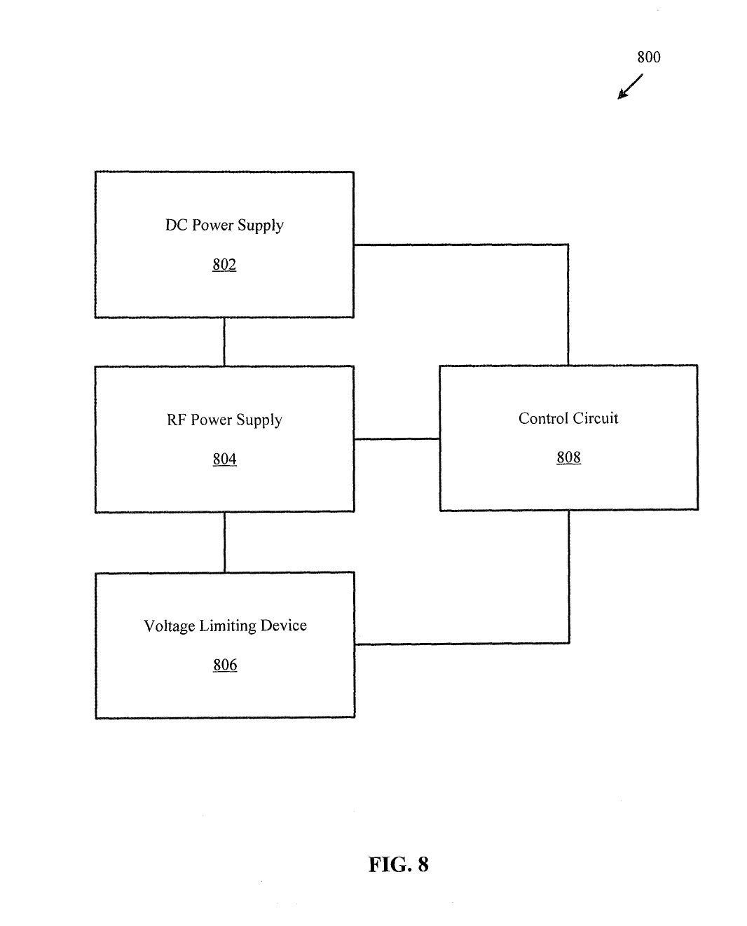

FIG. 8 illustrates a system to apply an RF and pulsed DC waveform combined with reverse voltage threshold to a cathode of a sputtering deposition process 800. As illustrated,

FIG. 8 includes a DC power supply 802, an RF power supply 804, a reverse voltage limiting device 806, and a control circuit 808. The DC power supply 802 applies a pulsed-DC waveform 302 to a cathode of a sputtering deposition chamber. The RF power supply 804 applies an RF waveform 304 to a cathode. A reverse voltage limiting device 806 limits the reverse voltage of a pulsed-DC waveform 302. The reverse voltage limiting device 806 may include any suitable signal modification circuits such as capacitors, inductors, selected low-pass or band-pass filters or other electronics as needed to achieve the desired responsiveness and voltage limiting for the particular application. Additionally, a control circuit 808 controls the interaction and timing of the DC power supply 802, the RF power supply 804, and the activation of the reverse voltage limiting device 806. For example, the control circuit 808 may ensure that the RF power supply 804 turns off prior to the DC power supply 802 applying a reverse DC voltage portion 310 to a cathode of a sputtering process.

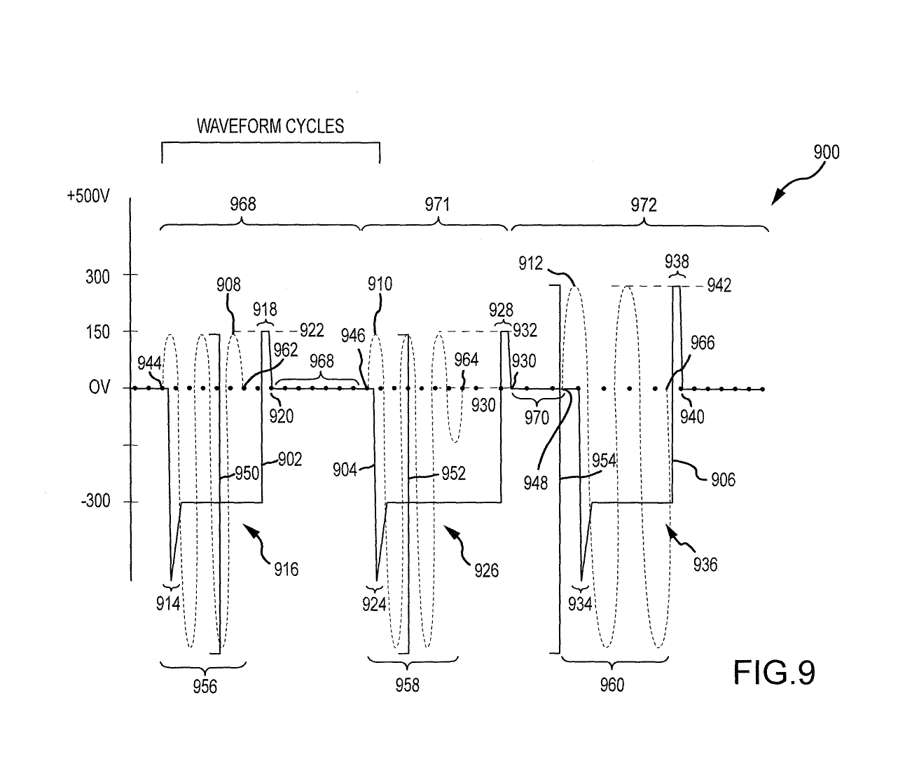

FIG. 9 illustrates an embodiment of a waveform 900 with modulated waveform sequences.

Waveform 900 includes a first pulsed-DC waveform 902, a second pulsed-DC waveform 904, and a third pulsed-DC waveform 906. Waveform 900 also includes and a first AC waveform 908, a second AC waveform 910, and a third AC waveform 912. Composite waveform 900 may be applied to a cathode of a sputtering deposition process in order to adjust the energy of the plasma.

Additionally the first pulsed-DC waveform 902 includes a first plasma ignition portion 914, a first steady-state portion 916, a first reverse DC voltage portion 918, and a first pulsed-DC termination point 920. The first pulsed-DC waveform 902 also includes a first reverse voltage limit 922.

Similarly, the second pulsed-DC waveform 904 includes a second plasma ignition portion 924, a second steady-state portion 926, a second reverse DC voltage portion 928, and a second pulsed-DC termination point 930. The second pulsed-DC waveform 904 also includes a second reverse voltage limit 932.

Further, the third pulsed-DC waveform 906 includes a third plasma ignition portion 934, a third steady-state portion 936, a third reverse DC voltage portion 938, and a third pulsed-DC termination point 940. The third pulsed-DC waveform 906 also includes a third voltage limit 942.

In an embodiment, the application of waveform 900 to a cathode ignites a plasma in a sputtering deposition chamber. In an embodiment, the plasma ignition occurs contemporaneous with plasma ignition portions 914, 924, and 934. In another embodiment, the application of an AC waveform, such as AC waveform 908, 910 and/or 912 causes a plasma to ignite. During plasma ignition, ions are generated. During this initial plasma ignition, there is a broader distribution of electron energies.

When a waveform 900 is applied to a cathode of a sputtering deposition chamber, generation of positive ions continues through the duration of a steady-state portion 916, 926, and 936. The distributions of the ion energies stabilizes during the steady state portion to a lower average electron energy value than in the plasma ignition phase.

Thus, the duration of steady state portion to the plasma ignition portion may be controlled to affect the energy distribution of ions in the plasma sheath. For example, the ratio between first plasma ignition portion 914 and first steady-state portion 916 may be larger than the ratio between the second plasma ignition portion 924 and the second steady-state potion 926.

The positive charge of created ions causes the ions to propel toward a negatively charged cathode, which is on or near a target. The resulting collision with the target propels target material toward a substrate for deposition. The energy of the ions impacting the target translates into higher energy of ejected material. Accordingly, the controlling the ratio between the steady state portion and the plasma ignition portion allows one to control the energy of the target material, and thus the resulting thin film quality.

The steady-state portions 916, 926, and 936 may have the same or different voltages. The voltage applied to the cathode during a steady-state portion affects properties of the plasma sheath. It may be desirous to alter the steady-state voltage from waveform to waveform. For example, steady-state portions 916, 926, and 936 may have a voltage that is set at −25, −50V, −60V, −70V, −80V, −90V, −100V, −110V, −120V, −130V, −140V, −150V, −160V, −170V, −180V, −190V, −200V, −210V, −220V, −230V, −240V, −250V, −260V, −270V, −280V, −290V, −300V, −310V, −320V, −330V, −340V, −350V, −360V, −370V, −380V, −390V, −400V, −410V, −420V, −430V, −440V, −450V, −460V, −470V, −480V, −490V, and −500V. Any suitable voltage may be chosen.

In the waveform 900 illustrated, a first reverse DC voltage portion 918 occurs after the first steady state portion 916, a second reverse DC voltage portion 928 occurs after the second steady state portion 926, and a third reverse DC voltage portion 938 occurs after the third steady-state portion 936. When applied to a cathode, the reverse DC voltage portions 918, 926, and 936 changes the polarity of the cathode from negative to positive. The frequency and duration of the reverse pulse, the reverse-pulse voltage, and the stable voltage may vary among different sputtering applications. Further, these parameters may vary for during the application of a waveform over time.

Application of the reverse voltage portions may be depend on the specific sputtering environment. For example, in an embodiment where the process gas is Ar, and the deposition material is transparent conductive oxide (“TCO”), a reverse DC voltage portion may last for between 0.5 and 10 mircoseconds. In embodiments, the reverse DC voltage portion lasts for a microsecond. Additionally, a reverse voltage threshold may be set between 100 and 300 volts.

The reverse DC voltage portion may occur by design or may be caused intrinsically by shutting off a DC power supply. When applied to a cathode, the reverse DC voltage portion reverses the polarity of the cathode from negative to positive. When this reversal occurs in a sputtering deposition chamber, the positive ions will accelerate toward the now negatively charged substrate (or a negatively charged area near the substrate). This depletes the ion density of the plasma sheath and substantially halts the deposition of sputtered species.

In embodiments, it may be desirous to limit the magnitude of the reverse voltage. Accordingly, each reverse voltage limit 922, 932, and 942 limits the voltage. Limiting the magnitude of the reverse voltage limits the kinetic energy of the ions accelerating toward the substrate during a reverse DC voltage portion.

Limiting the reverse voltage may be accomplished through electronic devices along with analog and digital controllers. In some embodiments where the target is non-metallic, a reverse voltage limiting may interfere with the RF waveform. As described in greater detail above, the systems and methods disclosed herein account for this and prevent interference with the RF waveform while still allowing the reverse DC voltage to be limited.

As shown, full rest period 968 is present in waveform 900. If applied to a cathode, a full rest period 968 represents the time in which no pulsed-DC power and no AC power is supplied to the cathode. The full rest period 926 is defined as the time between the termination of the power and the next application of a power. For example, a second full rest period 970 is illustrated. A full rest period may not be present or may be of a short or long duration relative to the application of power. In addition, rather than a full rest period, a DC rest period or AC rest period may be present. A DC rest period is a rest period where only the AC power is applied to the cathode. Similarly, an AC rest period is a time when only the DC power is applied to the cathode.

As shown, waveform 900 has AC waveforms 908, 910, and 912 superimposed on the pulsed-DC waveforms 902, 904, and 906, respectively. An AC waveform has an AC waveform initiation point, such as first AC waveform initiation point 944, a second AC waveform imitation point 946, and a third waveform initiation point 948. Further the first AC waveform 908 has a first amplitude 950, the second AC waveform 910 has second amplitude 952, and the third AC waveform 912 has a third amplitude 954. Additionally, the first AC waveform 908 has a first frequency 956, the second AC waveform 910 has a second frequency 958, the third AC waveform 912 has a third frequency 960. The first AC waveform 908 has first AC termination point 962, the second AC waveform 910 has a second AC termination point 964, and the third AC waveform 912 has a third AC termination point 966.

It is believed that the AC waveforms may be used to increase the ion density in the plasma sheath. The extent to which the ion density increases depends on the frequency, duration, and amplitude of the AC waveform. Accordingly, varying the frequency, duration, and amplitude will allows one to control the ion density of the ion sheath. For example, when applying an AC waveform to a cathode, varying the frequency and the amplitude of the AC waveform will generate ions with certain energy distributions. Furthermore, the density of ions created in a plasma sheath is directly proportional to the frequency. For example, at 13.56 mhz an AC waveform may create ions at a faster rate than a lower frequency. Ion generation occurs during AC application duration until an AC power termination point. AC power termination point may occur sometime before a reverse DC voltage portion. Ensuring that the AC power termination point occurs before a reverse DC voltage portion may be accomplished by various analog and digital control techniques, or some combination of the two techniques. The RF waveform may be ±800 VAC to 2200 VAC@13.56 MHZ, but need not be limited to this frequency. By using the superimposed RF or any other modulated signal, the cathode voltage can be reduced, and ion/deposition energy can be better controlled. Similarly, the energy of the sputtered material can be better controlled through lower cathode voltages.

The AC initiation point may occur prior, during, or after the plasma initiation points. In embodiments, AC initiation points 944, 946, and 964 may occur at or near the same time as the plasma ignition portions 914, 924, and 934, respectively. When the first AC waveform 908 is applied to a cathode, first AC initiation point 944 marks the initiation of the application of the first AC waveform 908 to a cathode of a sputtering.

Composite waveform 900 has three waveform sequences. The first waveform sequence 968 includes the first pulsed-DC waveform 902, the first AC waveform 908, and the full rest period 968. The second waveform sequence 971 includes the second pulsed-DC waveform 904 and the second AC waveform 910. The third waveform sequence 972 includes the third pulsed-DC 906, the full rest period 970, and the third AC waveform 912.

While composite waveform 900 includes three waveform sequences, each with an AC waveform, a DC waveform, a reverse voltage period, and a reverse voltage limit (or threshold), a waveform sequence need not include as much. For example, a waveform sequence may include only an AC waveform or a DC waveform. The DC waveform may be a simple DC waveform with no DC reverse voltage period and no reverse voltage limit.

A waveform may have one or more waveform sequences. Each sequence of a waveform may vary. As illustrated in waveform 900, the first waveform sequence 968 includes a first steady-state portion 916 that is longer than second steady-state portion 926 of the second waveform 970. Further, the third AC amplitude 954 of the third waveform sequence 972 is greater than the second amplitude 952 of the second waveform sequence 970. Other variations between waveform sequences may be present. For example, the frequency, amplitude, and duration of an AC waveform may be modulated from waveform sequence to waveform sequence. Additionally, the voltage, the reverse DC portion, the reverse DC limit, and the duration of a pulsed-DC waveform may vary from sequence to sequence. Indeed, the duration and presence of a full rest, AC rest, and DC rest may also vary from sequence to sequence. Thus, each waveform sequence may be modulated from waveform sequence to waveform sequence. Sequencing a waveform allows for modulation of the waveforms applied to a cathode of a sputtering deposition chamber.

The use of modulated waveform sequences allows for finer control of deposition rates and thin-film quality. For example, through the use of waveform sequence modulation a user can change from rapid sputter rate to rapid ion generation.

By way of example, applying a composite waveform that includes a waveform sequence with several reverse voltage DC-waveforms with short steady-state DC durations (i.e., rapid DC pulsing) increases the density of high energy ions. Alternatively, applying a waveform sequence with several longer duration steady-state pulsed-DC waveforms decreases the density of high energy ions in the plasma sheath.

As such, modulating waveform sequences in a composition waveform may allow for the control ion/electron energy and densities to affect new plasma and film properties.

Modulation of a waveform occurs when at least one property of the waveform varies over time. While the disclosure discussed modulation of waveforms using the construct of variation between waveform sequences, it will be appreciated that such modulation may also be referred to as a modulated waveform. As such, a waveform is referred to as being modulated when the waveform has at least one characteristic that changes overtime. As described herein, these characteristics include, but are not limited to, AC waveform frequency, AC waveform amplitude, pulsed-DC steady state duration, pulsed-DC steady state voltage, reverse voltage portion voltage, reverse voltage portion duration, reverse voltage limit, and pause period.

It will be clear that the systems and methods described herein are well adapted to attain the ends and advantages mentioned as well as those inherent therein. Those skilled in the art will recognize that the methods and systems within this specification may be implemented in many manners and as such is not to be limited by the foregoing exemplified embodiments and examples. In other words, functional elements being performed by a single or multiple components and individual functions can be distributed among different components. In this regard, any number of the features of the different embodiments described herein may be combined into one single embodiment and alternate embodiments having fewer than or more than all of the features herein described as possible. For example, in an embodiment all the necessary electronics to generate the disclosed waveform may be implemented as part of the power supply. In an alternative embodiment, the control circuit and voltage limiting circuitry may be separately embodied in an independent component that can be used with a prior art power supply capable of delivering pulsed DC waveforms with a modulated RF component.

While various embodiments have been described for purposes of this disclosure, various changes and modifications may be made which are well within the scope of the disclosed methods. Numerous other changes may be made which will readily suggest themselves to those skilled in the art and which are encompassed in the spirit of the disclosure.

What is claimed:

1. A method of controlling ions in a sputtering system that includes at least one cathode, the method comprising:
generating a modulated power signal, wherein the modulated power signal includes a reverse voltage portion, the reverse voltage portion limited by a reverse voltage limit;
providing the modulated power signal to the least one cathode.

2. The method of claim 1, wherein generating a modulated power signal comprises:
generating an amplitude-modulated power signal.

3. The method of claim 1, wherein the reverse voltage limit is set at a voltage selected from the group consisting of:
+10V, +25V, +50V, +60V, +70V, +80V, +90V, +100V, +110V, +120V, +130V, +140V, +150V, +160V, +170V, +180V, +190V, +200V, +210V, +220V, +230V, +240V, +250V, +260V, +270V, +280V, +290V, +300V, +310V, +320V, +330V, +340V, +350V, +360V, +370V, +380V, +390V, and +400V.

4. The method of claim 1, wherein generating a modulated power signal comprises:
generating an pulse-width modulated power signal.

5. The method of claim 1, wherein generating a modulated power signal comprises:
generating a pulse-amplitude modulated power signal.

6. The method of claim 1, further comprising:
actively varying a characteristic of the modulated power signal while the sputtering system is sputtering to thereby impact film growth.

7. The method of claim 1, wherein the modulated power signal includes an AC signal.

8. The method of claim 7, wherein the reverse voltage limit limits at least a portion of the AC signal.

9. The method of claim 1, wherein the modulated power signal includes a DC signal, wherein the DC signal is limited by the reverse voltage limit.

10. The method of claim 1, further comprising:
varying the modulation of the modulated power signal to decrease ion density.

11. A method for controlling ion density in a sputtering system, the method comprising:
providing a power signal to the sputtering system, wherein the power signal includes by a reverse voltage limit; and
varying at least one characteristic of the power signal to control ion density, wherein the characteristic includes at least one AC waveform frequency, AC waveform amplitude, pulsed-DC steady state duration, pulsed-DC steady state voltage, reverse voltage portion voltage, reverse voltage portion duration, reverse voltage limit, and pause period, and power signal application period.

12. The method of claim 11 wherein the varied characteristic is frequency, wherein power is first applied at a high-frequency power signal to the cathode to thereby generate a first concentration of ions and then the power is applied at a lower frequency to thereby generate a second concentration of ions.

13. The method of claim 12 wherein the first concentration of ions has a greater density than the second concentration of ions.

14. The method of claim 12, wherein a sputtering rate is lower when the power is first applied at a higher frequency than when the power is then applied a lower frequency.

15. A system for controlling the power applied to cathode of a sputtering deposition chamber, the system comprising a pulsed-DC power supply, an AC power supply, and a control circuit, the system configured to perform the method of:
generating a modulated power signal, wherein the modulated power signal includes a reverse voltage portion, the reverse voltage portion limited by a reverse voltage limit;
providing the modulated power signal to the at least one cathode.

16. The system of claim 15, wherein generating a modulated power signal comprises:
generating an amplitude-modulated power signal.

17. The system of claim 15, wherein generating a modulated power signal comprises:
generating an frequency-modulated power signal.

18. The system of claim 15, wherein generating a modulated power signal comprises:
generating an pulse-width modulated power signal.

19. The system of claim 15, further comprising:
actively varying a characteristic of the modulated power signal while the sputtering system is sputtering to thereby impact film growth.

20. The system of claim 15, wherein the modulated power signal includes an AC signal.

21. The system of claim 20, wherein the reverse voltage limit limits at least a portion of the AC signal.

22. The system of claim 15, wherein the modulated power signal is modulated such that at least one characteristic of the power signal is modulated overtime, wherein the wherein the characteristic is selected from the group consisting of: AC waveform frequency, AC waveform amplitude, pulsed-DC steady state duration, pulsed-DC steady state voltage, reverse voltage portion voltage, reverse voltage portion duration, reverse voltage limit, and pause period.
